(19) United States
(12) Patent Application Publication
(10) Pub. No.: US 2026/0130149 A1
(43) Pub. Date: May 7, 2026

(54) OXIDE FILM ETCHING METHOD AND SUBSTRATE PROCESSING APPARATUS

(71) Applicant: Tokyo Electron Limited, Tokyo (JP)

(72) Inventors: Takashi KOBAYASHI, Nirasaki City (JP); Kensaku TANAKA, Nirasaki City (JP)

(21) Appl. No.: 19/424,833

(22) Filed: Dec. 18, 2025

Related U.S. Application Data
(63) Continuation of application No. PCT/JP2024/021387, filed on Jun. 12, 2024.

(30) Foreign Application Priority Data
Jun. 26, 2023 (JP) 2023-104385

(51) Int. Cl. H10P 50/00; C23C 16/34; H10P 14/43; H10P 50/28; H10W 20/00

(52) U.S. Cl. CPC H10P 50/73; H10P 14/43; H10P 50/283; H10W 20/035; C23C 16/345

(57) ABSTRACT

An oxide film etching method includes: forming a protective film of a metal or a metal nitride that does not contain silicon so as to cover a protection target film, among the protection target film containing silicon and a silicon-containing oxide film exposed on a surface of a substrate; supplying, to the substrate, a mixed gas including a hydrogen fluoride gas and an ammonia gas to react with the silicon-containing oxide film, and modifying the oxide film to generate a reaction product; and sublimating and removing the reaction product.

### CROSS-REFERENCE TO RELATED APPLICATIONS

This application is a bypass continuation application of International Patent Application No. PCT/JP2024/021387 having an international filing date of Jun. 12, 2024 and designating the United States, the international application being based upon and claiming the benefit of priority from Japanese Patent Application No. 2023-104385, filed on Jun. 26, 2023, the entire contents of which are incorporated herein by reference.

### TECHNICAL FIELD

The present disclosure relates to an oxide film etching method and a substrate processing apparatus.

### BACKGROUND

In a manufacturing process of semiconductor devices, a method is known in which a silicon oxide film, which is a natural oxide film present on a surface of a semiconductor wafer (hereinafter referred to as “wafer”) serving as a substrate, is dry-etched without using plasma.

This dry etching method is performed, for example, by a chemical oxide removal (COR) process, which modifies a silicon oxide film to generate a reaction product, and a post heat treatment (PHT) process, which sublimates and removes the reaction product.

For example, Patent Document 1 describes a wafer structure on which these processes are performed. Specifically, an HDP-SiO₂ film formed by a bias high-density plasma CVD (HDP-CVD) method is provided as an interlayer insulating film on an Si layer, and a contact hole reaching the Si layer is provided in the HDP-SiO₂ film. It is described that an SiN film, which is an insulator, is provided on a sidewall of the contact hole, and a sacrificial oxide film, which is a natural oxide film provided on a bottom of the contact hole, is removed by the aforementioned processes.

### PRIOR ART DOCUMENTS

### Patent Documents

Patent Document 1: Japanese U.S. Pat. No. 6,161,972

### SUMMARY

According to one embodiment of the present disclosure, an oxide film etching method includes: forming a protective film of a metal or a metal nitride that does not contain silicon so as to cover a protection target film, among the protection target film containing silicon and a silicon-containing oxide film exposed on a surface of a substrate; supplying, to the substrate, a mixed gas including a hydrogen fluoride gas and an ammonia gas to react with the silicon-containing oxide film, and modifying the oxide film to generate a reaction product; and sublimating and removing the reaction product.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1A is a longitudinal cross-sectional side view of a recess formed in a wafer according to an embodiment of the present disclosure.

FIG. 1B is a longitudinal cross-sectional side view of a recess in a comparative embodiment.

FIG. 2A is a first longitudinal cross-sectional side view of the recess according to the embodiment.

FIG. 2B is a second longitudinal cross-sectional side view of the recess according to the embodiment.

FIG. 2C is a third longitudinal cross-sectional side view of the recess according to the embodiment.

FIG. 2D is a fourth longitudinal cross-sectional side view of the recess according to the embodiment.

FIG. 2E is a fifth longitudinal cross-sectional side view of the recess according to the embodiment.

FIG. 3 is a plane view of a substrate processing apparatus according to the embodiment.

FIG. 4 is a longitudinal cross-sectional side view illustrating a first processing module of the substrate processing apparatus.

FIG. 5 is a longitudinal cross-sectional side view illustrating a second processing module of the substrate processing apparatus.

FIG. 6 is a longitudinal cross-sectional side view illustrating a third processing module of the substrate processing apparatus.

FIG. 7 is a graph illustrating experimental results of a preliminary test.

FIG. 8 is an SEM image illustrating experimental results of an example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

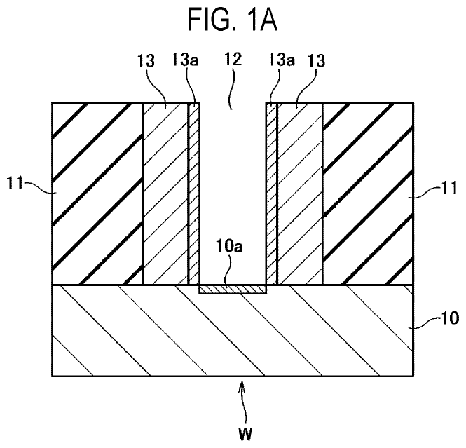

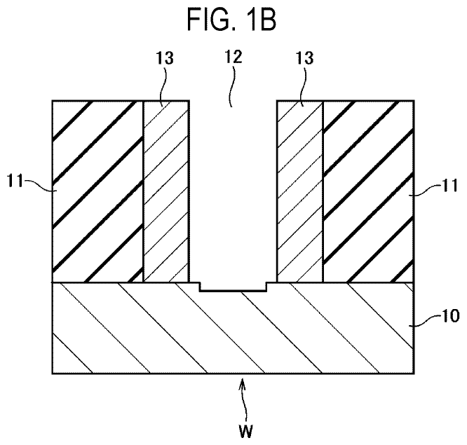

In describing an embodiment of an oxide film etching method according to the present disclosure, a configuration of a wafer W, which is a workpiece substrate of the method, is described. FIG. 1A is a longitudinal cross-sectional side view illustrating a portion of a surface layer of the wafer W before processing. A base layer of the wafer W is, for example, an Si layer 10 composed of silicon (Si). A silicon oxide (SiOₓ) layer 11 is formed on the Si layer 10. The SiOₓ layer 11 is used as an interlayer insulating layer.

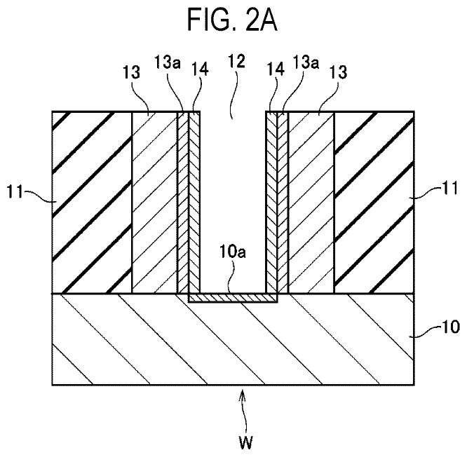

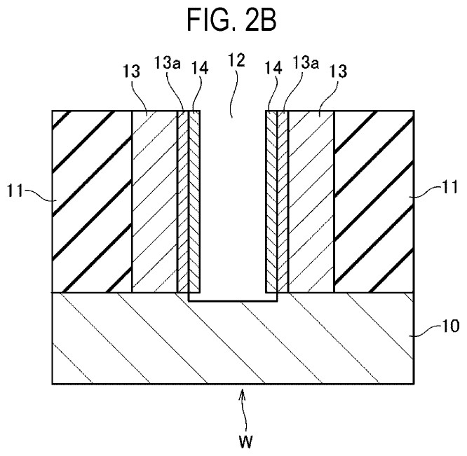

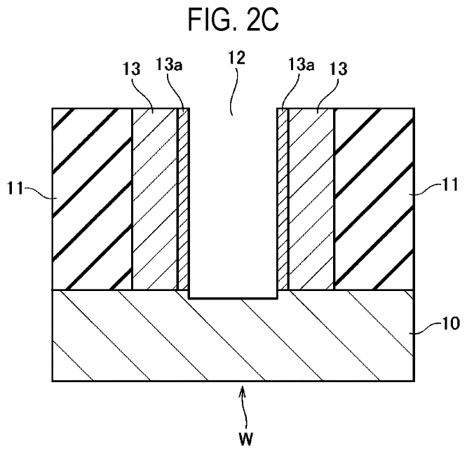

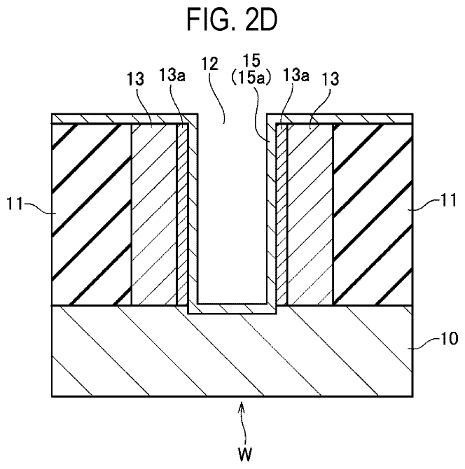

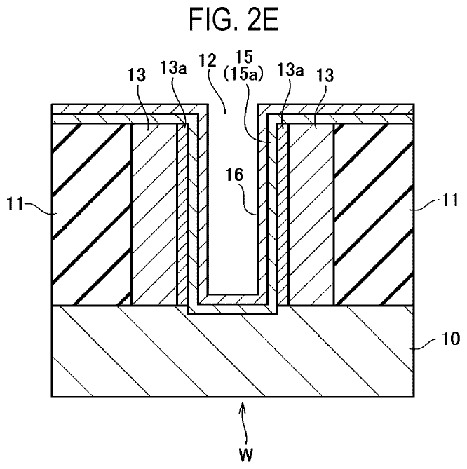

Longitudinally elongated recesses 12 formed by etching processing are provided in the SiOₓ layer 11, so as to be open at a surface of the wafer W. In addition, in FIGS. 1A and 1B and FIGS. 2A to 2E, a single recess 12 is extracted and illustrated. Each recess 12 is provided so as to reach the Si layer 10, and is formed so as to provide a contact metal film (hereinafter also simply referred to as “contact film”) and a wiring layer, which are connected to the Si layer 10. To meet a recent demand for miniaturization of semiconductor circuits, the recesses 12 are formed to have, for example, a width of about 10 nm to 20 nm, and are formed at small intervals.

A bottom surface of the recess 12 is constituted by the Si layer 10. A silicon oxide film 10a, which is naturally oxidized, for example, when the wafer W is transported in an atmospheric environment, is formed on a surface of the Si layer 10 facing the recess 12. The silicon oxide film 10a corresponds to “silicon-containing oxide film” of the present disclosure. A side surface of the recess 12 is constituted by a silicon nitride (SiN) layer 13, which is used as a stopper during the etching processing. A thin damage film 13a, which is damaged by the etching processing or by ashing processing for resist removal, is formed on a side surface of the SiN layer 13 facing the recess 12. The damage film 13a has a thickness of, for example, about 1 nm to 2 nm, and contains, for example, a silicon nitride oxidized during transport. As such, the silicon oxide film 10a and the damage film 13a are exposed on the surface of the wafer W through the recess 12.

Regarding the wafer W having the above structure, after the silicon oxide film 10a with a high electric resistivity is removed by the COR and PHT processes described in Background, a contact film and a cap film constituting a portion of a wiring layer are formed. In addition, as illustrated in FIG. 2E to be described later, a cap film 16 may constitute a portion of the wiring layer as a barrier metal, for example, or may be removed without constituting the wiring layer.

Hereinafter, the COR and PHT processes are collectively referred to as “oxide film removal process.” Herein, before describing the etching method of the present disclosure, an etching method of a comparative embodiment compared with the etching method of the present disclosure is described.

The etching method of the comparative embodiment is described with reference to FIGS. 1A and 1B. In the etching method of the comparative embodiment, first, the oxide film removal process is performed on the wafer W including the structure illustrated in FIG. 1A. Therefore, the silicon oxide film 10a becomes a reaction product such as ammonium fluorosilicate (AFS) by mixed gases, which are described later, supplied in the COR process, and the reaction product is sublimated and removed by the PHT process. However, since the damage film 13a contains an oxidized silicon nitride as described above, processing of the COR process or PHT process also acts on a silicon oxide portion of the damage film 13a. Therefore, as illustrated in FIG. 1B, there is a possibility that the damage film 13a containing silicon and oxygen is also entirely removed in the oxide film removal process.

If the damage film 13a is removed, the width of the recess 12 may be increased by about 2 nm to 4 nm, which is a width enlargement that is unacceptable in nano-scale ultra-fine semiconductor wirings. Moreover, the removal of the damage film 13a corresponds to a case where a portion of the SiOₓ layer 11 between the recesses 12 disposed adjacent to each other is shaved. As a result, disposition intervals between the wiring layers formed in the recesses 12 become smaller, which may cause issues such as an increase in a leak current.

As a solution to the problem of removal of a portion of the SiN layer 13 (the damage film 13a), as described in the comparative embodiment, the oxide film etching method of the present disclosure and a resulting change in film shape are described with reference to FIGS. 2A to 2E. In the oxide film etching method of the present disclosure, prior to the oxide film removal process, a process of forming a protective film (hereinafter referred to as “protective film formation process”) for forming a protective film 14 on the damage film 13a corresponding to a protection target film is performed. By performing the oxide film removal process after covering the damage film 13a with the protective film 14, it is possible to remove the silicon oxide film 10a while preventing the removal of the damage film 13a. After the oxide film removal process, a process of removing the protective film 14 (“cleaning process”), a contact film formation process for forming a contact film 15, and a cap film formation process for forming the cap film 16 are performed in this order.

Hereinafter, the aforementioned series of processes of the present disclosure are described in detail with reference to FIGS. 2A to 2E illustrating a change in the surface of the wafer W. During the series of processes, a surrounding environment of the wafer W is set to a vacuum atmosphere. That is, the wafer W is not exposed to the atmosphere during the series of processes. Therefore, each processing process is performed in a state where the wafer W is accommodated within a processing container. Further, when different processing containers are used for the above-described multiple processing processes, the wafer W is vacuum-transported through a vacuum transport chamber to which these processing containers are connected (vacuum transport process).

In the protective film formation process, a film formation gas (hereinafter also referred to as “protective film formation gas”) for forming a protective film is supplied to the wafer W illustrated in FIG. 1A. A material having etching resistance against a dry etching gas (mixed gases including a hydrogen fluoride gas and an ammonia gas) supplied in the COR process is employed as the protective film. Examples of such a material may include metals and metal nitrides. In the following example, a case where TiN, which is a metal nitride, is used as the protective film is described.

The protective film formation gas is composed of a raw material gas containing a raw material of the protective film and a reaction gas that reacts with the raw material gas. The raw material gas is, for example, a metal-containing gas, specifically, a titanium (Ti)-containing gas, and more specifically, a titanium tetrachloride (TiCl₄) gas. The reaction gas is a gas that precipitates a metal contained in the metal-containing gas, and is, for example, a gas that reacts with the titanium-containing gas, and more specifically, an ammonia (NH₃) gas that reacts with the TiCl₄ gas to nitride Ti. Further, an inert gas used as a purge gas, for example, a nitrogen (N₂) gas may be supplied in parallel together with the mixed gases.

As illustrated in FIG. 2A, it is desirable that the protective film 14 be formed mainly on the damage film 13a, among the silicon oxide film 10a and the damage film 13a exposed on the surface of the wafer W, and be hardly formed on the silicon oxide film 10a. Therefore, in a processing module to be described later for performing the protective film formation process, film formation is performed without using plasma having a high energy directed to a substrate stage 55 on which the wafer W is placed. The film formation performs, for example, isotropic film formation by a thermal atomic layer deposition (ALD) method. Therefore, the protective film 14 may be preferentially formed on the damage film 13a formed on a surface orthogonal to the substrate stage 55 while preventing formation of TiN on the silicon oxide film 10a, which is a surface parallel to the substrate stage 55.

Further, in thermal ALD, cyclic film formation is performed in which the above-described raw material gas and reaction gas are alternately and repeatedly supplied with a purge gas interposed therebetween. Therefore, titanium, which is a metal contained in the metal-containing gas adhered to the surface of the wafer W, is precipitated and nitrided, thereby forming one molecular layer of titanium nitride (TiN) on the surface of the wafer W in each film formation cycle. At this time, an incubation time required for the precipitation of TiN constituting the protective film 14 is longer on the silicon oxide film 10a than on the SiN layer 13. It has been understood that the incubation time correlates with the number of film formation cycles, as indicated in a preliminary test to be described later. Hereinafter, the number of cycles until a start of film precipitation may be referred to as incubation cycles. In the present embodiment, the number of film formation cycles is set to be greater than the incubation cycles for the SiN layer 13, and is also set to be equal to or less than the incubation cycles for the silicon oxide film 10a. Therefore, the protective film 14 is selectively formed on the damage film 13a, among the silicon oxide film 10a and the damage film 13a.

In the present embodiment, the TiN film formed in this manner is used as the protective film 14. The protective film 14 formed of TiN hardly allows silicon and oxygen to diffuse from the damage film 13a, and has an extremely small content of silicon and oxygen. Further, since the protective film 14 contains nitrogen, it has good adhesion to the damage film 13a, and may effectively protect the damage film 13a from the mixed gases during the COR process even when formed relatively thin.

As illustrated in FIG. 2A, the formation of the protective film 14 narrows the width of the recess 12. A lower end of the protective film 14 covers two ends of the silicon oxide film 10a in a width direction from above. It is desirable that the protective film 14 be as thin as possible within a range where it is able to protect the damage film 13a in the oxide film removal process. By preventing an increase in a thickness of the protective film 14 so as not to narrow the width of the recess 12, it is possible to prevent an increase in contact resistance caused by a reduction in an embedding volume of a wiring material. In the present disclosure, the thickness of the protective film 14 is, for example, about 0.5 nm to 5 nm, and is desirably about 1 nm to 2 nm, so as to protect the damage film 13a and to ensure selective formation of the protective film 14 on the damage film 13a.

Next, the oxide film removal process is performed on the wafer W on which the protective film 14 has been formed. The oxide film removal process includes the COR process (a process of modifying an oxide film to generate a reaction product) in which the silicon oxide film 10a is modified into a reaction product, and the PHT process (a process of sublimating and removing the reaction product) in which the reaction product is sublimated. In the etching method of the present disclosure, the protective film 14 is not modified by the COR process and is not removed in the oxide film removal process. The damage film 13a covered by the protective film 14 is difficult to be modified into a reaction product and to be removed in the oxide film removal process, since the supply of the mixed gases supplied in the COR process is prevented. As illustrated in FIG. 2B, by the protective film formation process and the oxide film removal process, the damage film 13a covered by the protective film 14 remains, while the silicon oxide film 10a is removed. Then, a bottom of the recess 12 is in a state where the non-oxidized Si layer 10 is exposed.

Next, the cleaning process is performed in which a cleaning gas is supplied to the wafer W from which the silicon oxide film 10a has been removed, to remove the protective film 14.

Therefore, as illustrated in FIG. 2C, the protective film 14 is removed and the damage film 13a is exposed. The side surface of the recess 12 is constituted by the damage film 13a, and the width of the recess 12 is approximately the same as that of the recess 12 before the protective film formation process. By the processes described above, the recess 12 is in a state where a change in width is prevented and the non-oxidized Si layer 10 is exposed on the bottom surface of the recess 12.

Then, the contact film formation process is performed on the wafer W, from which the protective film 14 has been removed, to form the contact film 15, for example, a titanium (Ti) film. The contact film formation process is performed by plasma CVD in which anisotropic film formation is performed by supplying a gas for forming a contact film (hereinafter also referred to as “contact film formation gas”) to be described later. As illustrated in FIG. 2D, the formed contact film 15 is provided so as to cover the damage film 13a constituting a sidewall of the recess 12 and the Si layer 10 constituting the bottom of the recess 12. In addition, although not explicitly illustrated in the drawings, the contact film 15 tends to be thicker at the bottom of the recess 12 than at the sidewall of the recess 12. Further, since the contact film 15 is in contact with the damage film 13a and the Si layer 10, the contact film 15 is silicided due to Si diffusion, thereby forming a TiSi film 15a. The TiSi film 15a is in wide contact with the Si layer 10 at the bottom of the recess 12 and is formed with good dimensional accuracy at the sidewall of the recess 12.

The cap film formation process is performed in which the cap film 16, for example, a TiN film, is formed by supplying a gas for forming a cap film (hereinafter also referred to as “cap film formation gas”) to the wafer W on which the TiSi film 15a has been formed. When using a TiN film as the cap film 16, a gas common to the above-described protective film formation gas may be used as the cap film formation gas. The cap film formation process is performed, for example, by isotropic thermal ALD, similar to the protective film formation process. As illustrated in FIG. 2E, the formed cap film 16 is formed so as to cover the TiSi film 15a constituting the sidewall and bottom of the recess 12. The cap film 16 is made to have approximately the same thickness at the sidewall and bottom of the recess 12. Since the cap film 16 is formed on the TiSi film 15a formed with good dimensional accuracy, it is formed substantially according to a design value.

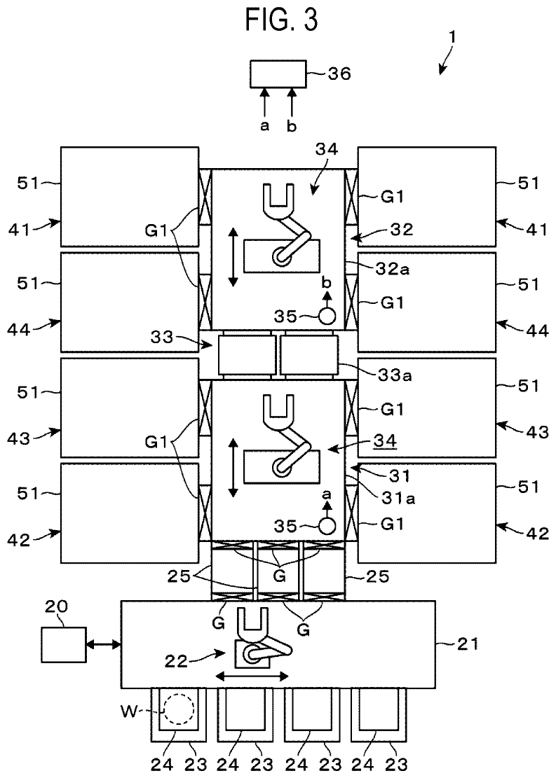

A substrate processing apparatus 1 capable of carrying out the above-described series of processes is described with reference to a plane view of FIG. 3. The substrate processing apparatus 1 includes a loader module 21, a load lock module 25, first and second vacuum transport modules 31 and 32, a connection module 33, and first to fourth processing modules 41 to 44. In the following description, the first vacuum transport module 31 and the second vacuum transport module 32 may be collectively referred to as vacuum transport modules 31 and 32.

Further, the first to fourth processing modules 41 to 44 may be simply referred to as processing modules 41 to 44.

The loader module 21, the load lock module 25, the first vacuum transport module 31, the connection module 33, and the second vacuum transport module 32 are linearly provided side by side in a front-rear direction in this order. In the following description relating to the substrate processing apparatus 1, a side on which the loader module 21 is located is referred to as a front side, and a side on which the second vacuum transport module 32 is located is referred to as a rear side.

The loader module 21 includes a housing, the inside of which is at atmospheric pressure, a transporter 22 for the wafer W provided within the housing, and a load port 23. In this example, four load ports 23 are provided side by side in a left-right direction on the front side of the housing. A transport container 24, called a front opening unified pod (FOUP), which accommodates the wafer W, is placed on each load port 23. The transporter 22 is configured, for example, with a multi-joint arm that is movable in the left-right direction, and is capable of transporting the wafer W between the transport container 24 on each load port 23 and each load lock module 25.

In this example, three load lock modules 25 are provided side by side in the left-right direction, when viewed from the front side. Each load lock module 25 includes a housing, and the housing is connected to the loader module 21 and the vacuum transport module 31 via gate valves G provided respectively at the front and rear sides of the housing. Then, each load lock module 25 is configured such that an internal pressure of the housing is changeable between an atmospheric pressure and a vacuum pressure while the gate valves G at the front and rear sides of the housing are closed. Further, a stage (not illustrated) on which the wafer W is placed is provided within the housing, and the stage is configured to be capable of transferring the wafer W to and from the transporter 22 and a vacuum transporter 34 to be described later, each of which accesses the load lock module 25.

The first and second vacuum transport modules 31 and 32 are configured similarly to each other and respectively include a housing 31a or 32a and the vacuum transporter 34 provided within the housing 31a or 32a. An exhaust port 35 is opened in each of the housings 31a and 32a, and one end of an exhaust pipe is connected to the exhaust port 35. The other end of the exhaust pipe is connected to an exhaust mechanism 36, which is configured, for example, with a turbo molecular pump, so that insides of the housing 31a and 32a are maintained in a vacuum atmosphere by exhaust through the exhaust port 35 by the exhaust mechanism 36.

In this example, two connection modules 33 are provided side by side in the left-right direction. Each connection module 33 includes a housing 33a, and the housing 33a is connected to each of the housings 31a and 32a of the vacuum transport modules 31 and 32. An inside of the housing 33a of the connection module 33 is also in a vacuum atmosphere at the same pressure as the insides of the housings 31a and 32a by exhaust of the exhaust mechanism 36. A stage (not illustrated) on which the wafer W is placed is provided inside the housing 33a, and the stage is configured to be capable of transferring the wafer W to and from the vacuum transporters 34 to be described later. The insides of the housings 31a and 32a of the first and second vacuum transport modules 31 and 32 and the inside of the housing 33a of the connection module 33, which are in a vacuum atmosphere by the exhaust mechanism 36, correspond to a vacuum transport chamber of the wafer W.

When viewed from the front side, the second processing module 42 and the third processing module 43, which are disposed side by side in the front-rear direction, are connected to left and right side surfaces of the housing 31a of the first vacuum transport module 31 via gate valves G1, respectively. The second processing module 42 is located at the front side, and the third processing module 43 is located at the rear side. The transfer of the wafer W between the second processing module 42, the third processing module 43, and the load lock module 25 is performed by the vacuum transporter 34 configured, for example, with a multi-joint arm that is movable back and forth.

When viewed from the front side, the fourth processing module 44 and the first processing module 41, which are disposed side by side in the front-rear direction, are connected to left and right side surfaces of the housing 32a of the second vacuum transport module 32 via gate valves G1, respectively. The fourth processing module 44 is located at the front side, and the first processing module 41 is located at the rear side. The transfer of the wafer W between the fourth processing module 44, the first processing module 41, and the connection module 33 is performed, for example, by the vacuum transporter 34.

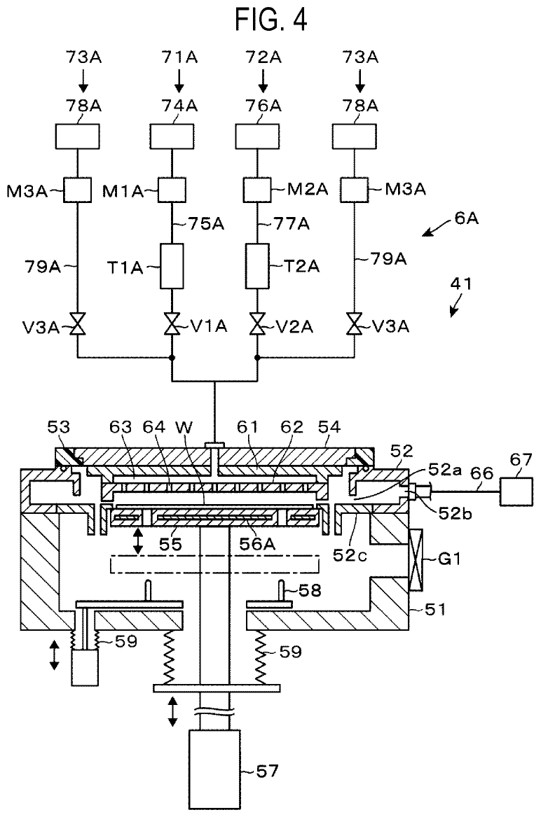

The correspondence between processes performed in each of the first to fourth processing modules 41 to 44 and the above-described series of processes is described. In the first processing module 41, the protective film formation process and the cap film formation process are performed. By executing the protective film formation process and the cap film formation process, both forming the same TiN film, in the first processing module 41, the number of processing modules is reduced and efficiency of these processes is improved. In the claims, a processing module that carries out the protective film formation process (a processing step of forming a protective film) is referred to as “first processing module”, and a processing module that carries out a cap film formation process (a processing step of forming a cap film) is referred to as “fifth processing module”. From this viewpoint, the processing module 41 illustrated in FIGS. 3 and 4 has a configuration common to the first processing module and the fifth processing module.

The COR process (a process of modifying an oxide film to generate a reaction product) is performed in the second processing module 42, the PHT process (a process of sublimating and removing the reaction product) is performed in the third processing module 43, and the contact film formation process is performed in the fourth processing module 44. Each of the processing modules 41 to 44 includes a processing container 51, the inside of which is exhausted to a vacuum atmosphere, and a substrate stage 55 provided within the processing container 51 to place the wafer W thereon, and each processing process is performed within the processing container 51.

The substrate processing apparatus 1 includes a controller 20, which is a computer, and the controller 20 includes a program. The program incorporates instructions (steps) for carrying out the above-described processing and transport processes of the wafer W. This program is stored in a non-transitory computer-readable storage medium such as a compact disk, hard disk, DVD, or non-volatile memory, and is read from the storage medium and installed in the controller 20.

The controller 20 outputs control signals to each part of the substrate processing apparatus 1 according to the program, thereby controlling the operation of each part. Specifically, the operations of the processing modules 41 to 44, the opening/closing of the gate valves G and G1, the operation of the transporter 22, the operation of the vacuum transporter 34, the operation of the exhaust mechanism 36, the pressure switching within the load lock module 25, and the like are controlled. The control of the operations of the processing modules 41 to 44 specifically includes, for example, temperature control of the wafer W by supplying power to heaters 56A to 56C to be described later, control of supply and stop of each gas into the processing container 51, and, if a radio frequency power supply is provided, control of plasma generation by on/off of the radio frequency power supply. The control operations of the controller 20 carried out in the COR process, PHT process, protective film formation process, cleaning process, contact film formation process, and cap film formation process correspond to processing steps. Further, the control operations for transporting the wafer W to each processing container 51 in order to perform these processes correspond to transport steps.

Regarding transport paths of the wafer W in the substrate processing apparatus 1, the wafer W is first transported in an order of the transport container 24→the loader module 21→the load lock module 25→the first vacuum transport module 31→the connection module 33→the second vacuum transport module 32→the first processing module 41. Then, the wafer W on which the protective film formation process has been performed in the first processing module 41 is transported in an order of the first processing module 41→the second vacuum transport module 32→the connection module 33→the first vacuum transport module 31→the second processing module 42. The wafer W on which the COR process has been performed in the second processing module 42 is transported in an order of the second processing module 42→the first vacuum transport module 31→the third processing module 43.

Then, the wafer W on which the PHT process has been performed in the third processing module 43 is transported in an order of the third processing module 43→the first vacuum transport module 31→the connection module 33→the second vacuum transport module 32→the fourth processing module 44. The wafer W on which the contact film formation process has been performed in the fourth processing module 44 is transported in an order of the fourth processing module 44→the second vacuum transport module 32→the first processing module 41, and then the cap film formation process is performed. The wafer W on which the cap film formation process has been performed is transported in an order of the first processing module 41→the second vacuum transport module 32→the connection module 33→the first vacuum transport module 31→the load lock module 25→the loader module 21, and is returned to the transport container 24.

Next, the first processing module 41 in which the protective film formation process and the cap film formation process are performed is described with reference to a longitudinal-cross-sectional side view of FIG. 4. The processing container 51 of the first processing module 41 is formed of, for example, aluminum. A transport port of the wafer W is formed at a sidewall of the processing container 51, and the gate valve G1 for opening or closing the transport port is provided. An annular exhaust duct 52 having, for example, a rectangular cross-sectional shape is disposed on an upper portion of the sidewall of the processing container 51. A slit 52a is provided along an inner peripheral surface of the exhaust duct 52, and an exhaust port 52b is formed at an outer wall of the exhaust duct 52. A ceiling wall 54 is provided on an upper surface of the exhaust duct 52 to block an upper opening of the processing container 51 via an insulating member 53, and a gap between the exhaust duct 52 and the insulating member 53 is hermetically sealed with a seal ring.

The substrate stage 55 is provided in an inside of the processing container 51 to horizontally support the wafer W. The substrate stage 55 is formed in a disk shape using a ceramic material such as an aluminum nitride (AlN) or a metal material such as an aluminum or nickel alloy. In this example, the heater 56A for heating the wafer W is embedded in the substrate stage 55, and the heater 56A heats the wafer W to, for example, 700 degrees C to 1,000 degrees C in the protective film formation process and the contact film formation process. An outer peripheral region of an upper surface and a side surface of the substrate stage 55 are covered with a cover member formed of ceramics such as alumina.

The substrate stage 55 is connected to a lift 57 provided below the processing container 51 via a support member, and is configured to be vertically movable between a processing position indicated by the solid line in FIG. 4 and a transfer position of the wafer W indicated by the one-dot dashed line below that. In FIG. 4, reference numeral 52c denotes a partition member for vertically partitioning the inside of the processing container 51 together with the substrate stage 55 raised to the processing position. Three (only two are illustrated) support pins 58 are provided below the substrate stage 55 within the processing container 51 so as to be vertically movable by a lift provided below the processing container 51. The support pins 58 are configured to be inserted into through-holes of the substrate stage 55 at the transfer position and to be capable of protruding or retracting with respect to an upper surface of the substrate stage 55, and are used for transferring the wafer W between the vacuum transporter 34 of the second vacuum transport module 32 illustrated in FIG. 3 and the substrate stage 55. In FIG. 4, reference numeral 59 denotes a bellows that partitions an internal atmosphere of the processing container 51 from an outside air and expands or contracts along with the vertical movement of either the substrate stage 55 or the support pins 58.

A shower head 61 for supplying various gases into the processing container 51 in a shower form is provided in the processing container 51 so as to face the substrate stage 55. The shower head 61 includes a main body fixed to the ceiling wall 54 of the processing container 51 and a shower plate 62 connected to an underside of the main body, and an inside of the shower head forms a gas diffusion space 63. A downwardly protruding annular protrusion is formed on a peripheral edge of the shower plate 62, and a gas discharge hole 64 is formed at a flat surface inside the annular protrusion. A gas introduction hole communicating with the gas diffusion space 63 is formed at the ceiling wall 54 and the main body of the shower head 61, and a gas supply mechanism 6A for protective film formation is connected to the gas introduction hole.

The gas supply mechanism 6A includes a raw material gas supply 71A configured to supply a raw material gas containing a raw material of the protective film 14 into the processing container 51, and a reaction gas supply 72A configured to supply a reaction gas that reacts with the raw material gas. Further, the gas supply mechanism 6A includes two purge gas supplies 73A configured to supply a purge gas. The raw material gas supply 71A includes a supply source 74A and a supply path 75A of the raw material gas, and the supply path 75A is provided with a flow rate adjuster M1A, a storage tank T1A, and a valve V1A from an upstream side.

The reaction gas supply 72A includes a supply source 76A and a supply path 77A of the reaction gas, and the supply path 77A is provided with a flow rate adjuster M2A, a storage tank T2A, and a valve V2A from an upstream side. Each purge gas supply 73A includes a supply source 78A and a supply path 79A of the purge gas, and each supply path 79A is provided with a flow rate adjuster M3A and a valve V3A. The supply path 79A of one purge gas supply 73A is connected to the supply path 75A of the raw material gas for purging the raw material gas, and the supply path 79A of the other purge gas supply 73A is connected to the supply path 77A of the reaction gas for purging the reaction gas. As described above, the raw material gas supply 71A, the reaction gas supply 72A, and the purge gas supply 73A are configured to supply the raw material gas, the reaction gas, and the purge gas, respectively, alone into the processing container 51.

The processing container 51 is connected to a vacuum exhaust path 66 via the exhaust port 52b, and a vacuum exhauster 67 configured, for example, with a vacuum pump is provided on a downstream side of the vacuum exhaust path 66 and is configured to execute vacuum exhaust of gases within the processing container 51. For example, an APC valve (not illustrated) as a pressure regulating valve is provided on the vacuum exhaust path 66 between the processing container 51 and the vacuum exhauster 67.

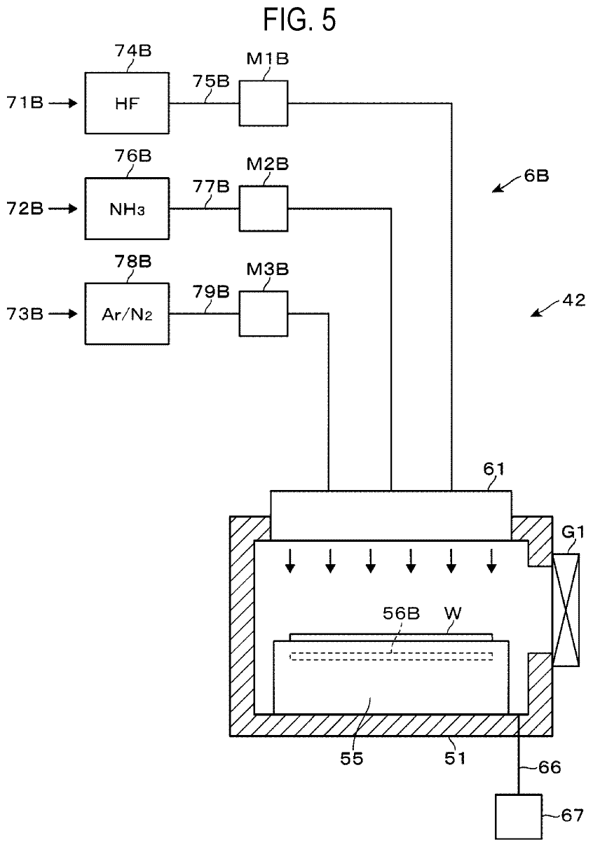

Next, the second processing module 42 for performing the COR process is described with reference to a longitudinal cross-sectional side view of FIG. 5, focusing on differences from the first processing module 41. For example, at a lower portion of the processing container 51, the vacuum exhauster 67 is connected via the vacuum exhaust path 66 provided with an opening/closing valve. The heater 56B is provided in an inside of the substrate stage 55. The heater 56B is configured to regulate a temperature of the upper surface of the substrate stage 55, for example, by circulating and supplying a temperature regulating fluid to a conduit, and is also configured to heat the wafer W placed on the substrate stage 55 to a heating temperature of 60 degrees C or higher.

Gases supplied by a mixed gas supply mechanism 6B for the COR process connected to the shower head 61 are a hydrogen fluoride (HF) gas, an NH₃ gas, and an inert gas, and the mixed gas supply mechanism 6B includes an HF gas supply 71B, an NH₃ gas supply 72B, and an inert gas supply 73B. The HF gas supply 71B includes a supply source 74B and a supply path 75B of the HF gas, and the supply path 75B is provided with a flow rate adjuster M1B. The NH₃ gas supply 72B includes a supply source 76B and a supply path 77B of the reaction gas, and the supply path 77B is provided with a flow rate adjuster M2B. The inert gas supply 73B includes a supply source 78B and a supply path 79B for supplying an argon (Ar) gas and a N₂ gas, and the supply path 79B is provided with a flow rate adjuster M3B. Downstream ends of the respective supply paths 75B, 77B and 79B are connected to the shower head 61.

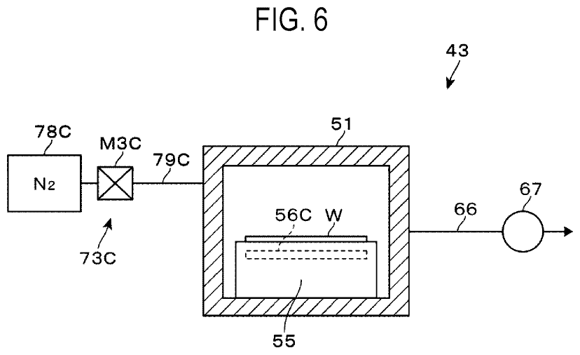

Next, the third processing module 43 for performing the PHT process is described with reference to FIG. 6, focusing on differences from the first processing module 41. The heater 56C of the third processing module 43 is, for example, a heater using resistance heat, and is configured to heat the wafer W placed in the third processing module 43 to a temperature higher than the temperature of the wafer W placed in the second processing module 42.

Further, the third processing module 43 includes, for example, an inert gas supply 73C for supplying an inert gas such as N₂ gas. The inert gas supply 73C includes a supply source 78C and a supply path 79C of the N₂ gas, and the supply path 79C is provided with a flow rate adjuster M3C. The inert gas supply 73C is capable of promptly purging a reaction product sublimated within the processing container 51 and also performing adjustment of an internal pressure of the processing container 51. Sublimation of the reaction product is achieved by regulating at least one of the temperature of the wafer W or the internal pressure of the processing container 51. From this viewpoint, the heater 56C and the vacuum exhauster 67 provided in the third processing module 43 correspond to a sublimation processor of the present embodiment.

The fourth processing module 44 in which the contact film formation process and the cleaning process are performed is described. The fourth processing module 44 of the present embodiment is configured to form a Ti film as the contact film 15. For example, the fourth processing module 44 includes the same configuration as the first processing module 41 described with reference to FIG. 4. On the other hand, the fourth processing module 44 differs from the first processing module 41 in the types of gases supplied from a gas supply mechanism and in including a configuration for plasma generation. In the following description, components common to the first processing module 41 described with reference to FIG. 4 are given the reference numerals described in the relevant drawing.

A gas supply mechanism (not illustrated) of the fourth processing module 44 is configured to supply a raw material gas and a reaction gas for contact film formation, a cleaning gas, and a purge gas into the processing container 51. The raw material gas for contact film formation is a gas containing a raw material of the contact film, and is, for example, a Ti-containing gas, specifically, a TiCl₄ gas. The reaction gas for contact film formation is a gas that reacts with the raw material gas, and is, for example, a gas that reacts with the Ti-containing gas, specifically, a hydrogen (H₂) gas that reacts with the TiCl₄ gas.

The cleaning gas is a gas for removing the protective film 14, and is, for example, a gas including a halogen compound gas, specifically, a chlorine trifluoride (ClF₃) gas. The purge gas is, for example, an inert gas capable of purging various gases supplied in the fourth processing module 44 and diluting the cleaning gas, and is specifically an Ar gas. This diluting gas is supplied as needed in order to adjust a concentration of ClF₃ gas.

The gas supply mechanism includes a TiCl₄ gas supply, an H₂ gas supply, a purge gas supply, and a cleaning gas supply. These supplies, similarly to the first processing module 41, each include a supply source and a supply path of various gases, and a flow rate adjuster is provided in each supply path. Downstream sides of the respective supply paths are, for example, connected individually to the shower head without being merged.

Then, the fourth processing module 44 constitutes a capacitively coupled plasma processing apparatus including the shower head 61 forming an upper electrode and the substrate stage 55 forming a lower electrode, in order to form the contact film by plasma CVD. A radio frequency power source for supplying radio frequency power for plasma generation is connected to the shower head 61 forming the upper electrode via a matcher, and the substrate stage 55 forming the lower electrode is grounded (both not illustrated).

In the contact film formation process, when radio frequency power is applied to the shower head 61, the TiCl₄ gas, H₂ gas and Ar gas supplied into the processing container 51 are ionized to generate plasma. Therefore, the contact film 15 is formed on the wafer W, placed in a space between the shower head 61 and the substrate stage 55, by plasma CVD.

In the contact film formation process, an internal pressure of the processing container 51 is regulated to a set pressure, for example, 666 Pa (5 Torr), and a temperature of the substrate stage 55 is regulated to, for example, 400 degrees C. In the cleaning process, the internal pressure of the processing container 51 is regulated to a set pressure, for example, 266 Pa (2 Torr), and the temperature of the substrate stage 55 is regulated to, for example, 300 degrees C.

An operation of executing a series of processes on the wafer W by using the substrate processing apparatus 1 including the configuration described above is described with reference to FIGS. 3 to 6 illustrating the substrate processing apparatus 1 as well as FIGS. 2A to 2E illustrating film changes. First, when the vacuum transporter 34 in the vacuum transport module 31 receives the workpiece wafer W from the load lock module 25 illustrated in FIG. 3, it transports the wafer W toward the first processing module 41 located at the rearmost side.

Thereafter, the gate valve G1 of the first processing module 41 illustrated in FIG. 4 is opened, and the vacuum transporter 34 introduces the wafer W into the processing container 51 through a loading port. Then, the wafer W is transferred from the vacuum transporter 34 to the substrate stage 55 by using the support pins 58, the vacuum transporter 34 is retracted from the processing container 51, and the gate valve G1 is closed.

As described above, the first processing module 41 is capable of performing both the protective film formation process and the cap film formation process, but first performs the protective film formation process. The internal pressure of the processing container 51 and the temperature of the wafer W are regulated according to recipe in the protective film formation process. Subsequently, as described above, various protective film formation gases are repeatedly supplied to the processing container 51 in a predetermined order. This film formation cycle may be performed within a range of, for example, about 30 to 60 times in consideration of the incubation cycle described above, and is specifically performed 30 times. Therefore, the protective film 14, which is a TiN film, is formed on the damage film 13a, while formation of the protective film 14 on the silicon oxide film 10a is prevented (FIG. 2A).

When the protective film formation step is completed, the wafer W on which the protective film 14 has been formed is unloaded from the first processing module 41 in the reverse procedure to that at the time of loading. Then, the wafer W is transported toward the second processing module 42 located at the frontmost side. Thereafter, the wafer W is loaded into the second processing module 42 in the same procedure as that at the time of loading into the first processing module 41, and the COR process is performed. Internal pressure regulation of the processing container 51 and temperature regulation are performed according to recipe in the COR process. Next, mixed gases for the COR process are supplied, for example, simultaneously into the processing container 51. Therefore, the silicon oxide film 10a may be modified to generate a reaction product while avoiding modification of the damage film 13a covered with the protective film 14.

When the COR process is completed, the wafer W on which the reaction product has been formed is unloaded from the second processing module 42 in the same procedure as in the first processing module 41, and is loaded into the third processing module 43 located second from the front side, and the PHT process is performed. Internal pressure regulation of the processing container 51 and temperature regulation are performed according to recipe in the PHT process, and an inert gas is supplied, thereby performing heat treatment of the wafer W. The reaction product of the heat-treated wafer W sublimates, whereby the silicon oxide film 10a is removed (FIG. 2B).

After completion of the PHT process, the wafer W in which the silicon oxide film 10a has disappeared is unloaded from the third processing module 43 and is loaded into the fourth processing module 44 located third from the front side. When the wafer W is transported from the third processing module 43 to the fourth processing module 44, the wafer W is not exposed to an atmospheric environment since the wafer W is transported through the first vacuum transport module 31, the second vacuum transport module 32, and the connection module 33, which are transport paths in a vacuum atmosphere. Accordingly, it is possible to prevent the surface of the Si layer 10 exposed within the recess 12 from being re-oxidized by the atmospheric atmosphere. The cleaning process is performed on the wafer W from which the silicon oxide film 10a has been removed and which has been loaded into the fourth processing module 44. In the cleaning process, internal pressure regulation of the processing container 51 and temperature regulation are performed according to recipe setting of the process, and cleaning gases with adjusted flow rates are simultaneously supplied. Therefore, the protective film 14 of the wafer W is removed (FIG. 2C).

After completion of the cleaning process, the contact film formation process is successively performed without unloading the wafer from the fourth processing module 44.

Since the contact film formation process is performed under the vacuum atmosphere within the processing container 51 in which the cleaning process has been performed, it is possible to achieve good overall processing efficiency and to reduce the number of processing modules. In the fourth processing module 44, internal pressure regulation of the processing container 51 and temperature regulation are performed according to recipe setting in the contact film formation process. Contact film formation gases are supplied, for example, simultaneously and radio frequency power is supplied from the power supply to the shower head 61. By such plasma CVD, the contact film 15 is formed on the surface of the wafer W from which the silicon oxide film 10a and the protective film 14 have been removed (FIG. 2D). The contact film 15 within the recess 12 becomes the TiSi film 15a due to diffusion of Si from the damage film 13a or the Si layer 10.

When the contact film formation process is completed, the wafer W with the TiSi film 15a (contact film 15) formed on the surface of the wafer W is unloaded from the fourth processing module 44 in the same procedure and is reloaded into the first processing module 41 located at the rearmost side. As described above, the first processing module 41 is capable of performing both the protective film formation process and the cap film formation process, but performs the cap film formation process at this timing. Since recipe of the pressure, temperature, and film formation gases in the cap film formation process is generally the same as the recipe in the protective film formation process, the first processing module 41 may be commonly used in both the protective film formation process and the cap film formation process. Film formation cycles in this process are performed, for example, within a range of about 30 to 90 times. Therefore, the cap film 16 is formed on the TiSi film 15a (contact film 15) (FIG. 2E).

The wafer W with the cap film 16 formed is loaded into the load lock module 25 and is then returned to the transport container 24 through the loader module 21. As described above, according to the substrate processing apparatus 1 and the oxide film etching method of the present disclosure, it is possible to effectively remove the silicon oxide film 10a in the oxide film removal process for removing the silicon oxide film 10a, and to prevent a width enlargement of the recess 12 in the oxide film removal process.

### Modification

The protective film formation process in the embodiment of the present disclosure is not limited to thermal ALD, and may also be performed by another film forming method such as chemical vapor deposition (CVD) other than ALD that does not use plasma, for example. In a case such as CVD in which a film thickness is regulated by film formation time, selective film formation on the damage film 13a may be performed, for example, by regulating film formation gas supply time and utilizing the difference in incubation time. Further, various gas compositions, temperature regulation, and others in the above-described series of processes are merely examples, and different gas compositions, temperature regulation, and other may be adopted.

The processes in the embodiment of the present disclosure need not necessarily be performed respectively in the corresponding processing modules 41 to 44 described above. For example, the protective film formation process and the cap film formation process are both performed in the first processing module 41, but may be performed in different processing modules. In this case, for improvement of throughput, two first processing modules 41 may be provided in the substrate processing apparatus 1. Further, the COR process and the PHT process are performed in the second processing module 42 and the third processing module 43, respectively, but may both be performed in the second processing module 42.

Further, although an example of the disposition of the respective processing modules 41 to 44, the vacuum transport modules 31 and 32, and others has been described with reference to FIG. 3, the number and disposition of these may of course be changed. For example, one of the vacuum transport modules 31 and 32, which are part of the transport mechanism of the wafer W, may be configured to perform vacuum transport, and the other transport module may be in an atmospheric environment, as long as the wafer W does not come into contact with the atmospheric environment after removal of the silicon oxide film 10a.

In the oxide film removal process of removing the Si layer 10, which is one silicon-containing layer, the present disclosure prevents removal of the SiN layer 13, which is another silicon-containing layer. Therefore, an upper portion of the Si layer 10 and the SiN layer 13 constituting an inner wall surface of the recess 12 are not limited to the Si layer and the SiN layer, respectively, and may be other layers containing silicon. For example, an SiGe layer may be provided on the upper portion of the Si layer 10 to constitute the bottom of the recess 12. In this case, since an oxide film of the SiGe layer exposed on the bottom of the recess 12 contains a silicon oxide, it is similarly removed by the COR and PHT processes.

In addition, a shape of the recess 12 is not limited to the shape described in the present disclosure. For example, the bottom of the recess 12 illustrated as a flat surface may also have a fin shape protruding toward an opening or a recess shape concavely indented. Further, since the series of processes of the present disclosure may be applied to the damage film 13a and the silicon oxide film 10a disposed on the surface of the wafer W, these processes are not limited to targeting the damage film 13a constituting the sidewall of the recess 12 and the silicon oxide film 10a constituting the bottom of the recess 12. For example, the damage film 13a and the silicon oxide film 10a may be provided on a horizontal surface of the wafer W. Further, the damage film 13a of the SiN layer 13 has been described as an example of the protection target film, but the protection target film is not limited to the damage film 13a formed on the SiN layer, and may be a film formed on a layer of another composition.

Further, for example, the cleaning gas supply may be provided in the third processing module 43, and the cleaning process to remove the protective film 14 may be performed after the PHT process, after which the wafer W may be transported to the fourth processing module 44 to perform the contact film formation process. Also, if the protective film 14 is sufficiently thin and has little influence on the subsequent formation of the contact film 15 or the cap film 16, the protective film 14 may not be removed. In this case, the contact film 15 and the cap film 16 may be formed on the remaining protective film 14. Further, in this case, if the protective film 14 is formed as thin as possible, a thick contact film 15 may be formed while preventing narrowing of the width of the recess 12, thereby preventing an increase in contact resistance. Further, the embodiment of the present disclosure exemplifies the formation of the contact film 15 and the cap film 16 within the recess 12, but these are not essential components, and after removal of the silicon oxide film 10a, a metal layer serving as a wiring material may be formed directly within the recess 12.

The protective film 14 is desirably a TiN film, but may also be another metal film that does not contain silicon or silicon oxide. In this case, it is desirable that the another metal film be a material in which silicon diffusion from the damage film 13a or oxidation does not easily occur, to such an extent that the metal film is not removed in the COR and PHT processes and prevents damage to the damage film 13a. Also, it is desirable that the another metal film is composed of a material that does not melt, sublime, or peel off at the temperatures of the COR and PHT processes. Further, it is desirable that the another metal film has a shorter incubation time for the damage film 13a, which is the protection target film, than an incubation time for the silicon oxide film 10a. Examples of the another metal film may include materials such as tungsten (W) and ruthenium (Ru).

In addition, the embodiments disclosed herein should be considered to be illustrative and not limitative in all respects. The above embodiments may be omitted, replaced, modified, or combined in various forms without departing from the scope and spirit of the appended claims.

### EXAMPLE

### Preliminary Test

Differences in the incubation cycle correlated with the incubation time used for the film formation of the protective film 14 by thermal ALD in the protective film formation process were checked. Specifically, the incubation cycles of a TiN film with respect to (i) the silicon oxide film and (ii) the silicon nitride film were checked.

### A. Conditions of Preliminary Test

The first processing module 41 of the embodiment and blanket wafers, which are three silicon bare wafers having the same shape each having (i) the silicon oxide film and (ii) the silicon nitride film formed with a uniform thickness over the entire surface were used to check differences in a growth rate of the TiN film. Therefore, conditions such as the film formation recipe, the temperature of the wafer W, and pressure setting were kept the same, and changes in film thickness by the cycle count were checked.

### B. Results of Preliminary Test

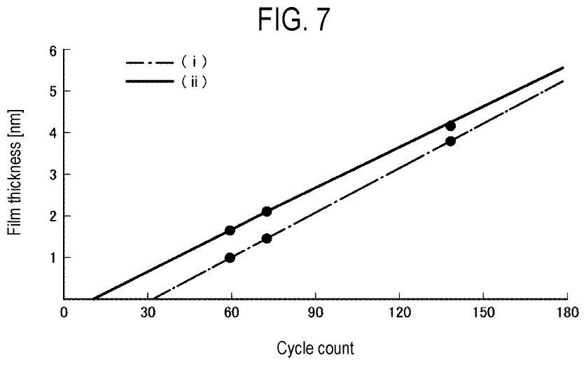

FIG. 7 is a graph illustrating results of the preliminary test. It was found that the film thickness of the TiN film and the cycle count with respect to each of (i) and (ii) has a linear relationship. Then, according to plots of the film thickness in FIG. 7 for each of (i) and (ii), precipitation of the TiN film was presumed to start from about 30 cycles for (i) the silicon oxide film and from approximately 0 cycles for (ii) the silicon nitride film. From this, it was inferred that, when forming the TiN film for each of (i) and (ii), there are different incubation cycles for the film formation cycles. Then, it was found that it is possible to perform selective film formation by setting the film formation cycles using differences in the cycle counts for the incubation cycles. For example, according to the results of the preliminary test, it is considered that if the cycle count is less than or equal to 30, the TiN film may be selectively formed on the silicon nitride film among the silicon oxide film and the silicon nitride film.

### Experiment

The protective film formation process in the embodiment was performed using the cycle count set based on the preliminary test results, and it was checked whether the TiN film was selectively formed. Specifically, it was checked that film formation was selectively performed on the silicon nitride film at the side surface of the recess, and not performed on the silicon oxide film at the bottom of the recess.

### A. Experimental Conditions

A silicon nitride layer was uniformly provided on a silicon layer of a prepare wafer, and a recess is formed in the silicon nitride layer such that the recess slightly penetrates an upper portion of the silicon layer. Regarding this wafer, 60 film formation cycles were performed under the same film formation conditions as in the preliminary test. After film formation of the TiN film, the recess of the wafer was checked with an SEM image.

### B. Experiment Results

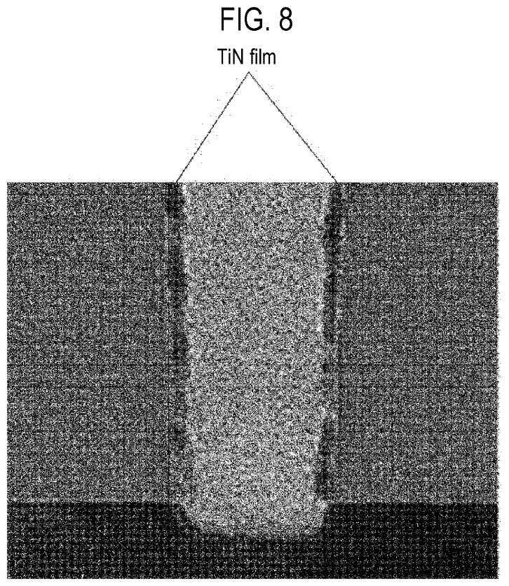

In the SEM image illustrated in FIG. 8, the damage film 13a, as described above with reference to FIG. 2C and other drawings, was formed on the surface of the silicon nitride layer, although it is not distinguishable from the silicon nitride layer constituting the sidewall of the recess. According to FIG. 8, the TiN film was formed on the silicon nitride layer on which the damage film 13a was formed. The thickness of the TiN film was approximately 2 nm. On the other hand, no distinct TiN film was observed on the surface of the Si layer constituting the bottom of the recess. Under the experimental conditions described above, the film formation cycles required to form a TiN film having a thickness of 1 to 2 nm are within a range of about 40 to 60 times. Through this experiment, it was checked that the TiN film may be selectively formed on the side surface of the recess of the wafer, for example, even with about 40 to 60 cycle counts.

According to the present disclosure in some embodiments, it is possible to prevent etching of a silicon-containing oxide film from removing a protection target film, which is exposed on a surface of a substrate and contains silicon.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An oxide film etching method comprising:
forming a protective film of a metal or a metal nitride that does not contain silicon so as to cover a protection target film, among the protection target film containing silicon and a silicon-containing oxide film exposed on a surface of a substrate;
supplying, to the substrate, a mixed gas including a hydrogen fluoride gas and an ammonia gas to react with the silicon-containing oxide film, and modifying the oxide film to generate a reaction product; and
sublimating and removing the reaction product.

2. The oxide film etching method of claim 1, wherein the protection target film constitutes a side surface of a recess formed in the surface of the substrate, and the oxide film constitutes a bottom surface of the recess.

3. The oxide film etching method of claim 2, wherein the protective film is formed by a chemical vapor deposition method without using plasma.

4. The oxide film etching method of claim 3, wherein the forming the protective film by the chemical vapor deposition method includes repeatedly performing:
supplying, to the substrate, a raw material gas containing a raw material of the metal; and
supplying, to the substrate, a reaction gas that precipitates the metal from the raw material or a reaction gas that nitrides the metal.

5. The oxide film etching method of claim 3, wherein the protective film is selectively formed on the protection target film by virtue of an incubation time in the forming the protective film by the chemical vapor deposition method being longer for the oxide film than for the protection target film.

6. The oxide film etching method of claim 1, wherein the protection target film is a silicon nitride film containing oxidized silicon.

7. The oxide film etching method of claim 1, wherein the protective film contains a metal selected from titanium, tungsten, or ruthenium.

8. The oxide film etching method of claim 1, comprising, after the sublimating and removing the reaction product:
forming a contact metal film on the surface of the substrate; and
forming a cap film so as to cover the contact metal film.

9. The oxide film etching method of claim 8, comprising:
removing the protective film after the sublimating and removing the reaction product and before the forming the contact metal film.

10. A substrate processing apparatus that processes a substrate, comprising:
a first processing module including a processing container including a stage on which the substrate is placed, and a film formation gas supply configured to supply a film formation gas into the processing container;
a second processing module including a processing container including a stage on which the substrate is placed, and a mixed gas supply configured to supply a mixed gas including a hydrogen fluoride gas and an ammonia gas into the processing container;
a third processing module including a processing container including a stage on which the substrate is placed, and a sublimation processor configured to carry out at least one of heating of the substrate or reduced-pressure exhaust within the processing container; and
a controller,
wherein the controller is configured to output a control signal to execute:
a processing step of supplying the film formation gas into the processing container of the first processing module while the substrate, in which a protection target film containing silicon and a silicon-containing oxide film are exposed on a surface of the substrate, is placed on the stage of the first processing module, and forming a protective film of a metal or a metal nitride that does not contain silicon so as to cover the protection target film;
a processing step of supplying the mixed gas into the processing container of the second processing module, while the substrate is placed on the stage of the second processing module, to react with the silicon-containing oxide film, and modifying the oxide film to generate a reaction product; and
a processing step of sublimating and removing the reaction product from the substrate, on which the reaction product has been generated, by the sublimation processor while the substrate is placed on the stage of the third processing module.

11. The substrate processing apparatus of claim 10, wherein the protection target film constitutes a side surface of a recess formed in the surface of the substrate, and the oxide film constitutes a bottom surface of the recess.

12. The substrate processing apparatus of claim 11, wherein the film formation gas forms the protective film by a chemical vapor deposition method without using plasma.

13. The substrate processing apparatus of claim 12, wherein the film formation gas supply includes a raw material gas supply configured to supply a raw material gas containing a raw material of the metal, and a reaction gas supply configured to supply, to the substrate, a reaction gas to precipitate the metal from the raw material or to nitride the metal, and
wherein the controller is configured to output a control signal to repeatedly execute supply of the raw material gas and supply of the reaction gas to the substrate during supply of the film formation gas.

14. The substrate processing apparatus of claim 12, wherein the film formation gas has a characteristic that an incubation time for the oxide film is longer than an incubation time for the protection target film in the forming the protective film by the chemical vapor deposition method, and
wherein the controller is configured to output a control signal to stop supply of the film formation gas after the protective film has been formed on the protection target film and before the protective film is formed on the oxide film, in order to selectively form the protective film on the protection target film.

15. The substrate processing apparatus of claim 10, wherein the protection target film is a silicon nitride film containing oxidized silicon.

16. The substrate processing apparatus of claim 10, wherein the protective film contains a metal selected from titanium, tungsten, or ruthenium.

17. The substrate processing apparatus of claim 10, comprising:
a fourth processing module including a processing container including a stage on which the substrate is placed, and a contact film formation gas supply configured to supply, into the processing container, a contact film formation gas to form a contact metal film; and
a fifth processing module including a processing container including a stage on which the substrate is placed, and a cap film formation gas supply configured to supply, into the processing container, a cap film formation gas to form a cap film,
wherein the controller is configured to output a control signal to execute, after the processing step of sublimating and removing the reaction product:
a processing step of placing the substrate on the stage of the fourth processing module and supplying the contact film formation gas into the processing container, thus forming the contact metal film on the surface of the substrate; and
a processing step of placing the substrate on the stage of the fifth processing module and supplying the cap film formation gas into the processing container, thus forming the cap film so as to cover the contact metal film.

18. The substrate processing apparatus of claim 17, wherein the third processing module or the fourth processing module includes a cleaning gas supply configured to supply, into the processing container, a cleaning gas to remove the protective film, and
wherein the controller is configured to output a control signal to execute:
a processing step of supplying the cleaning gas into the processing container to remove the protective film, after the processing step of sublimating and removing the reaction product and before the processing step of forming the contact metal film.

19. The substrate processing apparatus of claim 17, wherein the film formation gas and the cap film formation gas are a common gas, and
wherein the substrate processing apparatus comprises a common processing module shared by the first processing module and the fifth processing module.

20. The substrate processing apparatus of claim 17, comprising:
a vacuum transport chamber to which the processing container of the first processing module to the processing container of the fifth processing module are connected; and
a substrate transporter disposed within the vacuum transport chamber,
wherein the controller is configured to output a control signal to execute:
a transport step of transporting the substrate by the substrate transporter through the vacuum transport chamber to the processing container of one of the first processing module to the fifth processing module in which the processing step is carried out.
